(19) United States
(12) Patent Application Publication
(10) Pub. No.: US 2011/0242884 A1
(43) Pub. Date: Oct. 6, 2011

(54) Programming at Least One Multi-Level Phase Change Memory Cell

(75) Inventors: Evangelos S. Eleftheriou, Rueschlikon (CH); Angeliki Pantazi, Thalwil (CH); Nikolaos Papandreou, Thalwil (CH); Charalampos Pozidis, Thalwil (CH); Abu Sebastian, Adliswil (CH)

(73) Assignee: International Business Machines Corporation, Armonk, NY (US)

(21) Appl. No.: 13/069,512

(22) Filed: Jun. 6, 2011

(30) Foreign Application Priority Data
Mar. 31, 2010 (CH) 10158844.0

(51) Int. Cl. G11C 11/00

(52) U.S. Cl. 365/163; 365/148

(57) ABSTRACT

A method of applying at least one programming pulse to the a PCM cell for programming the PCM cell to have a respective definite cell state, the definite cell state being defined by a definite resistance level using an annealing pulse or a melting pulse. The respective definite cell state represents two information entities, a step of applying a first reading pulse to the respective programmed PCM cell to provide a first resistance value, a step of applying at least a second reading pulse to the respective programmed PCM cell to provide a second resistance value, the first reading pulse and the second reading pulse being different pulses; and a step of determining the respective definite cell state of the respective programmed PCM cell dependent on the respective provided first resistance value and the respective provided second resistance value.

The invention relates to a method and to a device for programming at least one multi-level Phase Change Memory (PCM).

### BACKGROUND OF THE INVENTION

Phase change memory (PCM) is a non-volatile solid-state memory technology that exploits the reversible, thermally-assisted switching of specific chalcogenides between certain states of different electrical conductivity.

PCM is a promising and advanced emerging non-volatile memory technology mainly due to its excellent features including low latency, high endurance, long retention and high scalability. PCM may be considered a prime candidate for Flash replacement, embedded/hybrid memory and storage-class memory. Key requirements for competitiveness of PCM technology may be multi-level cell functionality, in particular for low cost per bit and high-speed read/write operations, in particular for high bandwidth. Multilevel functionality, i.e. multiple bits per PCM cell, may be a way to increase capacity and thereby to reduce cost.

Multi-level PCM is based on storing multiple resistance levels between a lowest (SET) and a highest (RESET) resistance value. Multiple resistance levels or levels correspond to partial-amorphous and partial-crystalline phase distributions of the PCM cell. Phase transformation, i.e. memory programming, may be enabled by Joule heating. In this regard, Joule heating may be controlled by a programming current or programming pulse. Storing multiple resistance levels in a PCM cell is a challenging task. Issues like process variability, as well as intra-cell and inter-cell material parameter variations may give rise to deviations of the achieved resistance levels from their intended values.

In single-step programming approaches, single write pulses are applied in order to amorphize or crystallize a certain fraction of the phase change material of the PCM cell. The amplitude of the programming pulse is determined by the characteristic R-I programming curve of the PCM cell that consists of a left-side obtained by annealing pulses that are adapted to crystallize the phase change material and a right-side obtained by higher amplitude pulses that melt the material, i.e. melting pulses. Although, the programming curves of various cells exhibit similar overall behavior, there are variations of the PCM cells that may cause variations of the programming levels in multi-level storage.

One way to resolve this issue may be to resort to iterative programming schemes, in particular with multiple write-verify steps until a desired resistance level is reached.

In general, any iterative scheme aims to efficiently control the programming current through the cell in order to converge to the desired resistance level.

Schemes for adaptively controlling parameters of the programming pulse in iterative manner are shown in “Multilevel Phase-Change Memory Modeling and Experimental Characterization” by A. Pantazi, A. Sebastian, N. Papandreou, M. J. Breitwisch, C. Lam, H. Pozidis, E. Eleftheriou, E*PCOS2009.

Further, a “Three-dimensional simulation model of switching dynamics in phase change random access memory cells” is described by Dae-Hwang Kim, Florian Merget, Michael Forst and Heinrich Kurz, in Journal of Applied Physics 101. 064512/2007.

In conventional programming schemes, the cell level is defined using the resistance value read-back at a specific low voltage.

### SUMMARY OF THE INVENTION

According to an embodiment of a first aspect of the invention, a method for programming at least one multi-level Phase Change Memory (PCM) cell for storing at least two information entities in one resistance level of the PCM cell is provided. The method comprises the following steps:
a) applying at least one programming pulse to the at least one PCM cell for programming said respective PCM cell to have a respective definite cell state, the definite cell state being defined by a definite resistance level being the resistance value provided by a definite reading pulse and a type of the at least one applied programming pulse being an annealing pulse or a melting pulse, the respective definite cell state representing two information entities;
b) applying a first reading pulse to the respective programmed PCM cell to provide a first resistance value;
c) applying at least a second reading pulse to the respective programmed PCM cell to provide either a second resistance value or a current versus reading-pulse amplitude curve, the first reading pulse and the second reading pulse being different pulses; and
d) determining the respective definite cell state of the respective programmed PCM cell dependent on the respective provided first resistance value and either the respective provided second resistance value or the respective provided current versus reading-pulse amplitude curve.

In a wordline programming scheme of a multi-level PCM cell, there are two programming pulses providing the same resistance level of the PCM cell. One of the two programming pulses is an annealing pulse associated to a left slope of a U-shaped programming curve of the PCM cell. The other one of the two programming pulses is a melting pulse associated to a right slope of the U-shaped programming curve.

According to embodiments of the present invention, a two-dimensional programming scheme is presented, where the cell state is defined not only by the resistance value, but also by the type of the programming pulse, i.e. by whether the PCM cell has been programmed in the left slope or the right slope of the programming curve. Thus, according to embodiments of the present invention, there is a distinction if the resistance level is programmed using annealing pulses, i.e. the left slope of the programming curve, or melting pulses, i.e. the right slope of the programming curve.

Thus, the two-dimensional programming scheme according to embodiments of the invention may increase the storage capacity of the PCM cell, since two information entities or levels may be programmed in the same resistance value.

Therefore, the two-dimensional programming scheme according to embodiments of the invention may have the advantage that the storage levels of the PCM cell may be increased and thus more bits may be stored in one PCM cell.

Particularly, the cell state of the PCM cell may be defined by the resistance value and the phase distribution which depends on the programming region, i.e. the left and right programming slopes of the programming curve. The cell read-out of the PCM cell may take advantage of the fact that the non-linearity of the sub-threshold I-V curves is a function of the phase distribution in order to distinguish the programming regimes, i.e. the left and right programming slopes.

The definite cell state may also be denoted as target cell state. The definite resistance level may also be denoted as target resistance level.

An embodiment of an efficient read-out scheme may include two subsequent cell read operations with different read voltages or different reading pulses. A ramp reading pulse may also be used. The ramp pulse may be used to estimate the slope of the I-V characteristics.

According to an embodiment of the invention, an iterative programming scheme is used for programming said at least one multi-level PCM cell. The iterative programming scheme may use multiple write-verify steps for programming a respective definite resistance level of the PCM cell

According to an embodiment of a second aspect, the invention relates to a computer program comprising a program code for executing the method for programming at least one multi-level Phase Change Memory (PCM) cell when run on a computer.

According to an embodiment of a third aspect of the invention, a device for programming at least one multi-level Phase Change Memory (PCM) cell for storing at least two information entities in one resistance level of the PCM cell is suggested. The device comprises first means, second means, third means, and fourth means. Said first means are adapted to apply at least one programming pulse to the at least one PCM cell for programming said respective PCM cell to have a respective definite cell state, the definite cell state being defined by a definite resistance level and a type of the at least one applied programming pulse being an annealing pulse or a melting pulse, the respective definite cell state representing two information entities. Further, said second means are adapted to apply a first reading pulse to the respective programmed PCM cell to provide a first resistance value. Said third means are adapted to apply at least a second reading pulse to the respective programmed PCM cell to provide either a second resistance value or a current versus reading-pulse amplitude curve. The first reading pulse and the second reading pulse are different pulses or reading pulses. Moreover, said fourth means are adapted to determine the respective definite cell state of the respective programmed PCM cell dependent on the respective provided first resistance value and either the respective provided second resistance value or the respective provided current versus reading-pulse amplitude curve.

The respective means, e.g. said first means, said second means, said third means, and said fourth means, may be implemented in hardware or in software. If said means are implemented in hardware, it may be embodied as a device, e.g. as a computer or as a processor, or as a part of a system, e.g. a computer-system. If said means are implemented in software, it may be embodied as a computer program product, as a function, as a routine, as a program code or as an executable object.

An annealing pulse may be any pulse that heats the phase change material above the crystallization temperature, but below the melting temperature. A melting pulse may be any pulse that heats the material above its melting temperature.

In one embodiment of the method of the present invention, said PCM cell is controllable by two terminals, wherein the respective programming pulse may be embodied as a pulse in either one of the terminals and the respective reading pulse may be embodied as a pulse in either one of the terminals.

In a further embodiment, the two terminals are embodied as a bitline and a wordline.

In a further embodiment, said programming pulse is embodied as a wordline voltage pulse or a bitline current pulse.

In a further embodiment, said reading pulse is embodied as a bitline voltage pulse or a bitline current pulse.

In a further embodiment, said definite cell state is defined by the definite resistance level and by the phase distribution of the programmes PCM cell. The phase distribution of the programmed PCM cell may be dependent on the type of the at least one applied programming pulse being an annealing pulse or a melting pulse.

In a further embodiment, said step of determining the respective cell state of the respective programmed PCM cell may include a step of determining the resistance level and the phase distribution of the programmed PCM cell dependent on the respective provided first resistance value and either the respective provided second resistance value or the respective provided current versus reading pulse amplitude curve.

In a further embodiment, said step of determining the respective cell state of the respective programmed PCM cell may include a step of determining the type of the applied programming pulse by the steps:
providing a threshold value, where the threshold value may be different depending on the definite resistance level,
providing a measure being the magnitude of the difference between the first resistance value and the second resistance value
identifying the applied programming pulse as a melting pulse if the respective provided measure is greater than the provided threshold value, and
identifying the applied programming pulse as an annealing pulse if the respective provided measure is less than the provided threshold value.

Further embodiment, said step of determining the respective cell state of the respective programmed PCM cell may include a step of determining the type of the applied programming pulse by the steps:
providing a threshold value in log domain, the threshold value may be different depending on the definite resistance level,
providing a measure being the magnitude of the difference between the first resistance value and the second resistance value in the log domain
identifying the applied programming pulse as a melting pulse if the respective provided measure is greater than the provided threshold value, and
identifying the applied programming pulse as an annealing pulse if the respective provided measure is less than the provided threshold value.

In a further embodiment, said step of determining the respective cell state of the respective programmed PCM cell may include a step of determining the type of the applied programming pulse by the steps:
providing a threshold value, the threshold value may be different depending on the definite resistance level,
providing a measure being the slope of the provided current versus (vs) reading-pulse amplitude curve,
identifying the applied programming pulse as a melting pulse if the respective provided measure is greater than the provided threshold value, and
identifying the applied programming pulse as an annealing pulse if the respective provided measure is less than the provided threshold value.

In one embodiment of the device of the present invention, the definite cell state may be defined by the definite resistance level and by the phase distribution of the programmed PCM cell, the phase distribution of the programmed PCM cell being dependent on the type of the at least one applied programming pulse being an annealing pulse or a melting pulse.

In a further embodiment of the device of the present invention, said fourth means are adapted to determine the resistance level and the phase distribution of the programmed PCM cell dependent on the respective provided first resistance value and either the respective provided second resistance value or the respective provided current vs reading-pulse amplitude curve.

In a further embodiment of the device of the present invention, said fourth means may comprise first providing means, second providing means and identifying means. The first providing means may be adapted to provide a threshold value. The threshold value may be different depending on the definite resistance level. Furthermore, said second providing means are adapted to provide a measure being the difference between the first resistance value and the second resistance value. Moreover, said identifying means may be adapted to identify the applied programming pulse as a melting pulse, if the respective provided measure is greater than the provided threshold value, or as an annealing pulse, if the respective provided measure is less than the provided threshold value.

In a further embodiment of the device of the present invention, said fourth means may comprise first providing means, second providing means and identifying means.

The first providing means are adapted to provide a threshold value in log domain, wherein the threshold value is particularly different depending on the definite resistance level. Further, said second providing means are adapted to provide a measure being the difference between the first resistance value and the second resistance value. The identifying means are adapted to identify the applied programming pulse as a melting pulse, if the respective provided measure is greater than the provided threshold value, or as an annealing pulse, if the respective provided measure is less than the provided threshold value.

In a further embodiment of the device of the present invention, said fourth means may comprise first providing means, second providing means and identifying means.

Said first providing means are adapted to provide a threshold value, the threshold value may be different depending on the definite resistance level. Said second providing means are adapted to provide a measure being the slope of the provided current vs reading-pulse amplitude curve. Said identifying means are adapted to identify the applied programming pulse as a melting pulse, if the respective provided measure is greater than the provided threshold value, or as an annealing pulse, if the respective provided measure is less than the provided threshold value.

In general, where features are described herein with reference to an embodiment of one aspect of the invention, corresponding features may be provided in embodiments of another aspect of the invention. Preferred embodiments of the invention will now be described, by way of example, with reference to the accompanying drawings.

### BRIEF DESCRIPTION OF THE FIGURES

FIG. 1 shows an exemplary diagram of a wordline-based programming curve of a PCM cell;

FIG. 2 shows an exemplary diagram of a wordline-based programming curve of a PCM cell and different cell read-outs with different reading pulses;

FIG. 3 shows an embodiment of a sequence of method steps for programming at least one multi-level PCM cell;

FIG. 4 shows an exemplary diagram of I-V measurements in a sub threshold regime for annealing pulses;

FIG. 5 shows an exemplary diagram of I-V measurements in the sub threshold regime for melting pulses;

FIG. 6 shows an exemplary diagram of an estimation of an amorphous thickness of a PCM cell;

FIG. 7 shows an exemplary diagram of an estimation of the amorphous thickness of a PCM cell;

FIG. 8 shows an exemplary diagram for illustrating a read-out for two-dimensional programming;

FIG. 9 shows an exemplary diagram for illustrating the read-out for two-dimensional programming;

FIG. 10 shows a diagram illustrating experimental results of an embodiment of the present invention;

FIG. 11 shows a diagram illustrating experimental results of a further embodiment of the present invention;

FIG. 12 shows a block diagram of a first embodiment of a device for programming at least one multi-level PCM cell;

FIG. 13 shows a block diagram of a second embodiment of the device for programming at least one multi-level PCM cell,

FIG. 14 shows an example of a wordline-based current control of a PCM cell, and

FIG. 15 shows an example of a bitline-based current control of a PCM cell.

Like or functionally alike elements in the figures have been allocated the same reference signs if not otherwise indicated.

### DETAILED DESCRIPTION OF PREFERRED EMBODIMENTS

The present invention may be applied to multi-level Phase Change Memory (PCM) cells. Multi-level functionality, i.e. multiple bits per PCM cell, is a prominent way to increase the capacity and thereby to reduce costs. A multi-level PCM cell is based on storing multiple resistance levels between a lowest (SET) and a highest (RESET) resistance value. The multiple levels or multiple resistance levels of the PCM cell correspond to partial-amorphous (partial-RESET) and partial-crystalline (partial-SET) phase distributions. The phase change, i.e. the state programming, may be enabled by Joule heating, in particular by temperature or current control, and may be initiated electrically, in particular by a threshold switching.

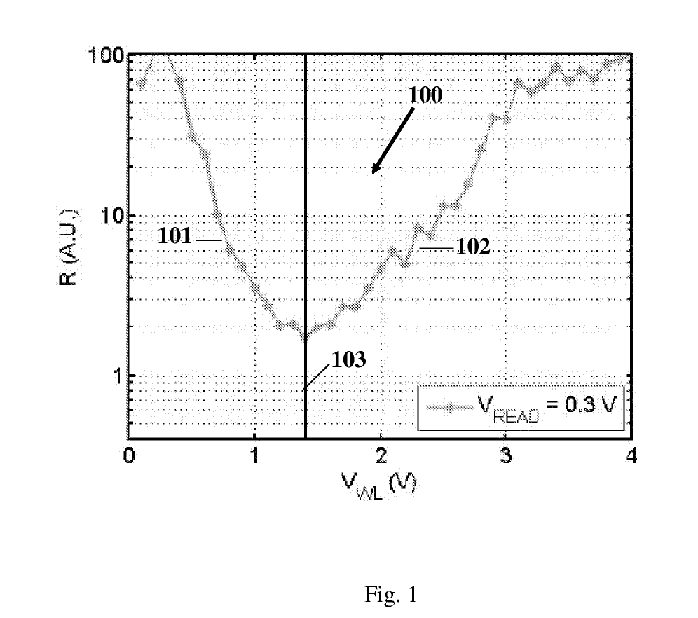

In FIG. 1, an exemplary diagram of a wordline-based programming curve 100 of a PCM cell is shown. The x-axis of FIG. 1 shows the wordline voltage VWL, and the y-axis shows the resistance value of the PCM cell read by a reading pulse V_{READ}=0.3 V.

The programming curve 100 of FIG. 1 has two possible operating regimes, namely a left slope 101 and a right slope 102. For illustration issues, the two slopes 101 and 102 of the programming curve 100 are divided by a cutting line 103. The cutting line 103 further indicates that wordline voltages VWL left from the cutting line 103 are annealing pulses, and wordline pulses right from the cutting line 103 are melting pulses.

Further, the left slope 101 of the programming curve 100 of FIG. 1 is obtained by annealing pulses that crystallize the phase change material of the PCM cell. Further, the right slope 102 of the programming curve 100 is obtained by higher amplitude pulses that melt the material, so-called melting pulses.

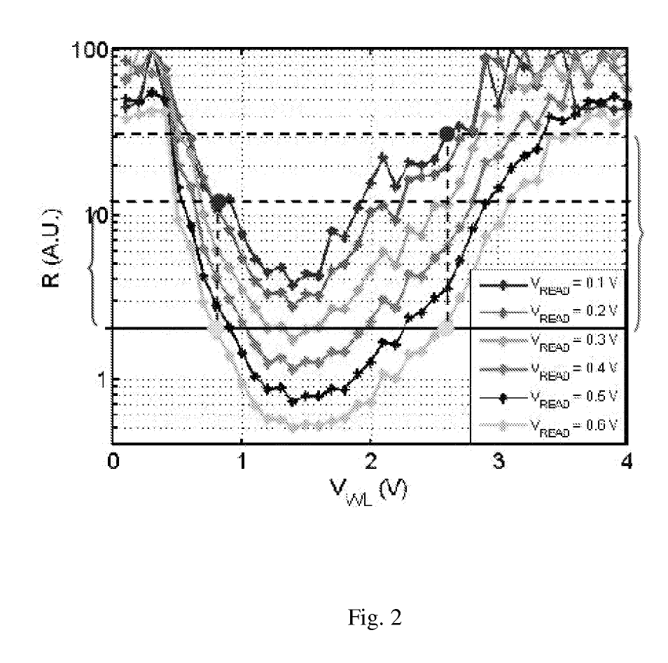

FIG. 2 shows an exemplary diagram of a wordline-based programming curve of a PCM cell and different cell read-outs with different reading pulses. With respect to FIG. 2, two cell states programmed in the two different regimes, namely by the left slope and the right slope, may have the same resistance level when read with a specific read voltage, e.g. V_{READ}=0.6 V, but may map into different resistance values, when read with a different read voltage, e.g. V_{READ}=0.1 V. Thus, at least two different reading pulses or pulses with different voltages are needed to differentiate the used programming regime. Thus, the used programming regime may be differentiated in dependence on different non-linearities in the I-V characteristics programmed in the left slope or the right slope.

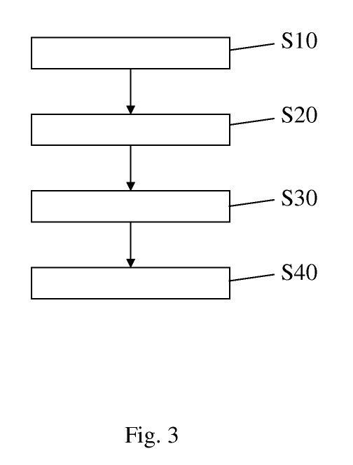

In this regard, FIG. 3 shows an embodiment of a sequence of method steps for programming at least one multi-level PCM cell.

The method of FIG. 3 has the following method steps S10-S40:

In the step S10, at least one programming pulse is applied to the PCM cell for programming the PCM cell to have a respective definite cell state. The definite cell state is defined by a definite resistance level and the type of the at least one applied programming pulse. The applied programming pulse may be an annealing pulse or a melting pulse. Annealing pulses and melting pulses result in different phase distributions of the PCM cell. The respective definite cell state may represent two information entities derived from the resistance level and the type of the applied programming pulse.

In particular, the definite cell state may be defined by the definite resistance level and by the phase distribution of the programmed PCM cell. The phase distribution of the programmed PCM cell may be dependent on the type of the at least one applied programming pulse being an annealing pulse or a melting pulse.

In the step S20, a first reading pulse is applied to the respective programmed PCM cell for providing a first resistance value. The first reading pulse may be a bitline pulse applied to a bitline coupled to the PCM cell.

In the step S30, at least a second reading pulse is applied to the respective programmed PCM cell for providing a second resistance value. Also, the second reading pulse may be a bitline pulse applied to the bitline coupled to the PCM cell. The first reading pulse and the second reading pulse are different pulses or reading pulses. In particular, the first reading pulse and the second reading pulse differ in their voltage amplitude.

In the step S40, the respective definite cell state of the respective programmed PCM cell is determined in dependence on the respective provided first resistance value and the respective provided second resistance value.

In particular, said step S40 may include that the resistance level and the phase distribution of the programmed PCM cell are determined dependent on the respective provided first resistance value, the respective provided second resistance value and an a-priori known non-linearity of a sub threshold current reading pulse curve of the programmed PCM cell.

Further, said step S40 may include that the type of the applied programming pulse may be determined by the following sub-steps: In a first sub-step, a threshold value is generated. In a second sub-step, a measure being the magnitude of the difference between the first resistance value and the second resistance value is provided. In a third sub-step, the applied programming pulse is identified as a melting pulse, if the provided measure is greater than the provided threshold value, or the applied programming pulse is identified as an annealing pulse, if the provided measure is less than the provided threshold value.

Particular, said provided threshold resistance value may be provided as a threshold resistance value in log domain.

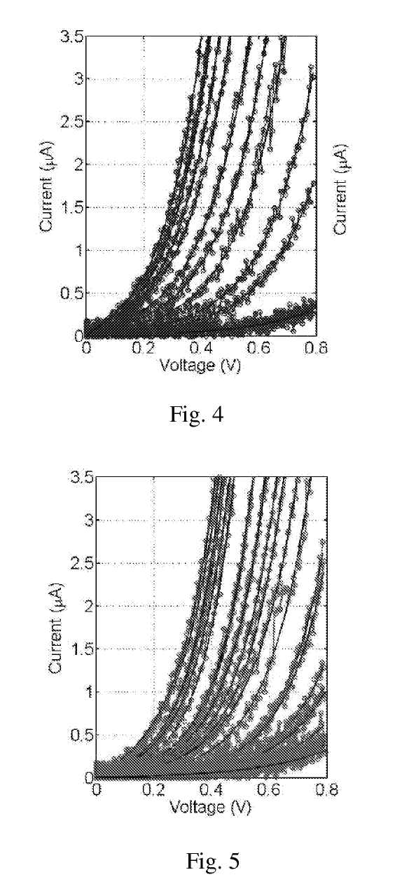

Furthermore, FIG. 4 shows an exemplary diagram of I-V measurements in a sub-threshold regime for annealing pulses. Moreover, in this regard, FIG. 5 shows an exemplary diagram of I-V measurements in the sub threshold regime for melting pulses. The x-axis of FIGS. 4 and 5 designates the voltage of the reading pulse and the y-axis designates the current provided in dependence on the reading pulse, respectively.

The phase distribution of the programmed PCM cell may be derived from the amorphous thickness of the programmed PCM cell. Further, the amorphous thickness of the programmed PCM cell may be derived from the equations:

$$I = \frac{1}{{R}_{0} β} sinh ( {V}_{a} β ) , β = q Δ z / kT 2 {u}_{a}$$

wherein
R₀ designates the low-field resistance,
Vₐ designates the applied voltage,
β designates the sub threshold slope,
q designates the elementary charge,
Δz designates the average distance between two traps,
k designates the Boltzmann constant,
T designates the temperature, and
uₐ designates the amorphous thickness.

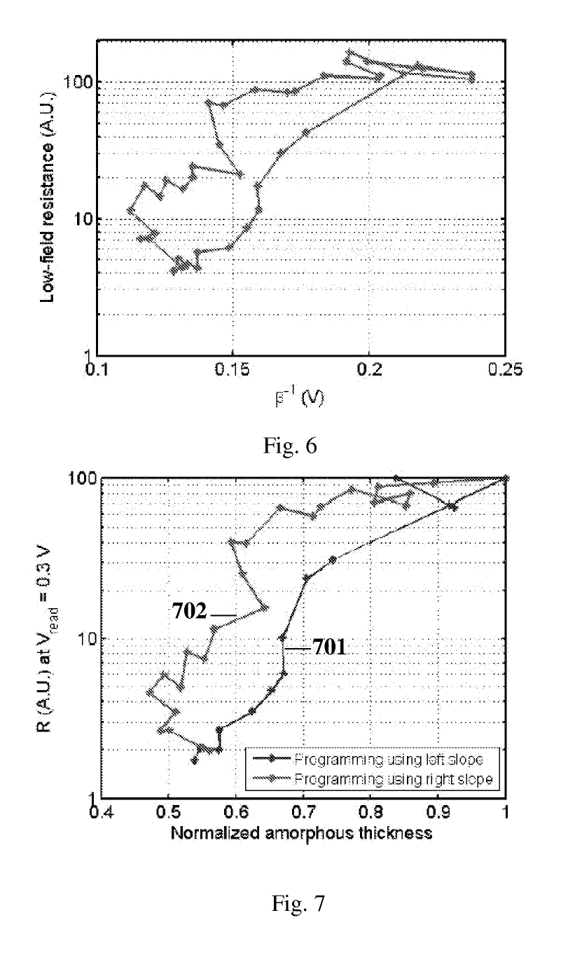

Moreover, FIGS. 6 and 7 show exemplary diagrams of an estimation of an amorphous thickness of a PCM cell. In this regard, the x-axis of FIG. 6 shows the inverse of the sub threshold slope β, and the y-axis of FIG. 6 shows the low-field resistance.

Further, with respect to FIG. 7, the x-axis shows the normalized amorphous thickness of the PCM cell, and the y-axis shows the resistance value read with a reading pulse of 0.3 V. The curve 701 of FIG. 7 is generated by programming using the left slope of the programming curve, wherein the curve 702 of FIG. 7 is generated by programming using the right slope.

FIGS. 6 and 7 show that the same resistance level may correspond to different effective thicknesses of the amorphous material dependent on the used programming regime, in particular depending on using the left slope or the right slope. Moreover, the same resistance value at a specific read voltage may correspond to a higher effective amorphous thickness, if the left slope is used for programming the PCM cell.

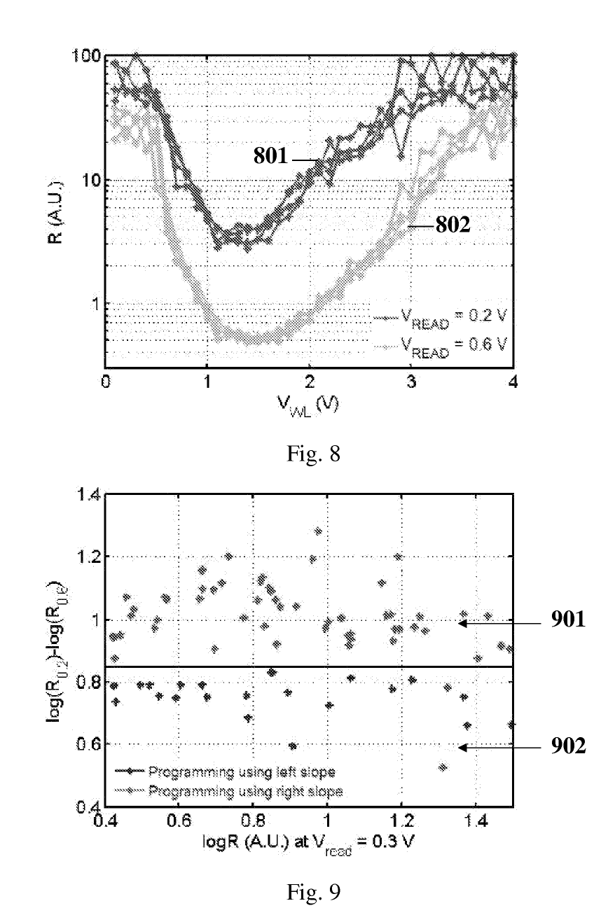

FIG. 8 shows an exemplary diagram for illustrating a read-out for two-dimensional programming. In FIG. 8, the x-axis shows the wordline programming pulse, and the y-axis shows the resistance value provided dependent on the reading pulse. Curves 801 of FIG. 8 are generated by using a reading pulse with a voltage amplitude of 0.2 V. In contrast, curves 802 of FIG. 8 are generated using a reading pulse of 0.6 V.

For the same example of using four cells, FIG. 8 shows wordline programming curves and FIG. 9 shows a corresponding read-out scheme.

With respect to FIG. 9, points 901 are programmed using the right slope and points 902 are generated using the right slope. With respect to FIG. 9, the difference in the log domain of two resistance values compared to a threshold value may determine the programming regime.

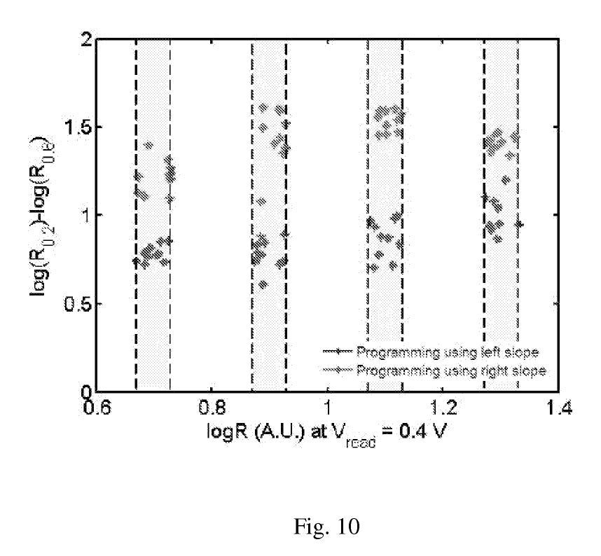

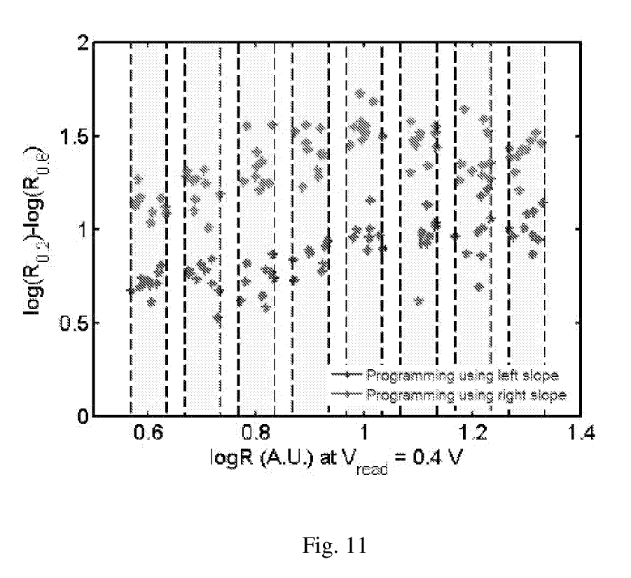

FIG. 10 shows a diagram illustrating experimental results of an embodiment of the present invention. In the embodiment of FIG. 10, four different resistance levels are used for the PCM cell. Further, FIG. 10 shows the measurements result differentiating the used programming slope. A further example with eight different resistance levels is shown in FIG. 11.

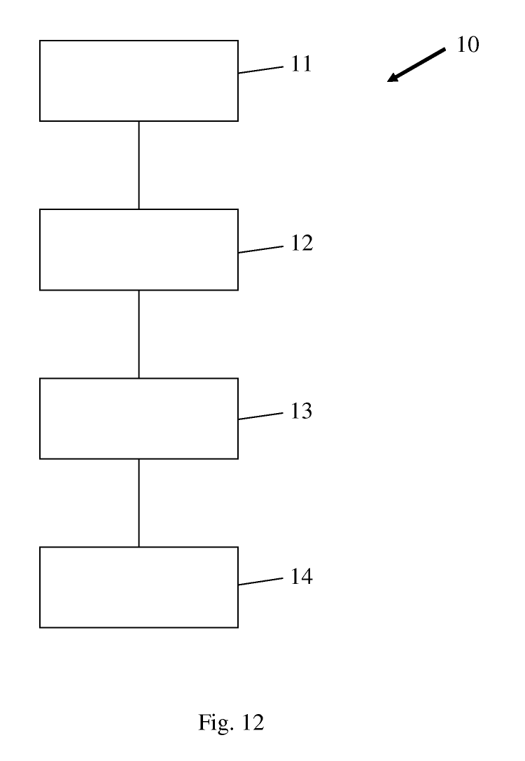

Moreover, FIG. 12 shows a block diagram of a first embodiment of a device 10 for programming at least one multi-level PCM cell. Said device 10 has first means 11, second means 12, third means 13 and fourth means 14.

Said first means 11 are configured to apply at least one programming pulse to the at least one PCM cell for programming said respective PCM cell to have a respective definite cell state. The definite cell state may be defined by a definite resistance level and a type of the at least one applied programming pulse being an annealing pulse or a melting pulse, the respective definite cell state representing two information entities.

Further, said second means 12 are adapted to apply a first reading pulse to the respective programmed PCM cell to provide a first resistance value.

Said third means 13 are adapted to apply at least a second reading pulse to the respective programmed PCM cell to provide a second resistance value. The first reading pulse and the second reading pulse are different pulses or reading pulses.

Said fourth means 14 are adapted to determine the respective definite cell state of the respective programmed PCM cell dependent on the respective provided first resistance value and the respective provided second resistance value or the respective provided current versus reading-pulse amplitude curve.

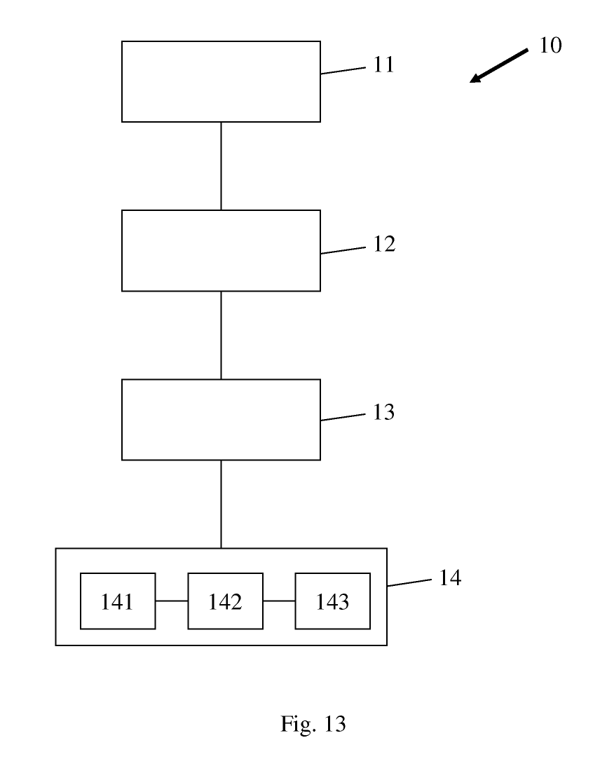

FIG. 13 shows a block diagram of a second embodiment of the device for programming at least one multi-level PCM cell. The second embodiment of FIG. 13 includes all features of said first means 11, said second means 12, and said third means 13 and embodies the fourth means 14.

In particular, said fourth means 14 may be adapted to determine the resistance level and the phase distribution of the programmed PCM cell dependent on the respective provided first resistance value and either the respective provided second resistance value or the respective provided current versus reading-pulse amplitude curve

Particularly, said fourth means 14 may comprise first providing means 141, second providing means 142 and identifying means 143. The first providing means 141 may be adapted to provide a threshold value. The threshold value may be different depending on the definite resistance level. Furthermore, said second providing means 142 are adapted to provide a measure being the difference between the first resistance value and the second resistance value. Moreover, said identifying means 143 may be adapted to identify the applied programming pulse as a melting pulse, if the respective provided measure is greater than the provided threshold value, or as an annealing pulse, if the respective provided measure is less than the provided threshold value.

Further, said second providing means 142 and said identifying means 143 may be embodied alternatively. In this regard, said second providing means 142 may be adapted to provide a measure being the slope of the provided current versus reading-pulse amplitude curve. Moreover, said identifying means 143 may be adapted to identify the applied programming pulse as a melting pulse, if the respective provided measure is greater than the provided threshold value, or as an annealing pulse, if the respective provided measure is less than the provided threshold value.

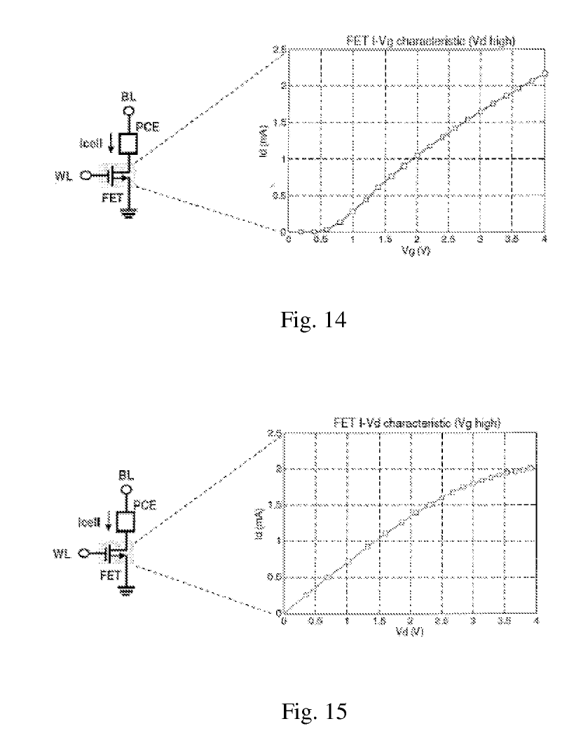

FIG. 14 shows an example of a wordline-based current control of a PCM cell, and FIG. 15 illustrates an example of a bitline-based current control of a PCM cell.

In this regard, the left parts of FIG. 14 and FIG. 15 respectively show a circuitry having a phase change element PCE and a field effect transistor FET as an access entity. Further, terminals to the bitline BL and to the wordline WL are shown. Furthermore, the right part of FIG. 14 shows an I-VG characteristic of the field effect transistor FET having a constant high VD. In an analogous way, the right part of FIG. 15 shows an I-VD characteristic of the FET having a constant high VG.

With respect to FIG. 14, the field effect transistor FET may be used as a current source. A high voltage VD, the drain voltage, may be applied across the bitline BL. The current Icell may be controlled by means of the gate voltage VG applied to the wordline WL.

With respect to FIG. 15, the field effect transistor FET may be used as a switch. In contrast to FIG. 14, a high voltage VG is applied at the wordline WL. The current Icell may be controlled by the drain voltage VD applied to the bitline BL.

All above mentioned embodiments of the method of the present invention may be embodied by respective means to be a respective embodiment of the device for programming at least one multi-level PCM cell above mentioned third aspect of the invention present invention.

What has been described herein is merely illustrative of the application of the principles of the present invention. Other arrangements and systems may be implemented by those skilled in the art without departing from the scope and spirit of this invention.

1. A method for programming at least one multi-level Phase Change Memory, PCM, cell for storing at least two information entities in one resistance level of the PCM cell, comprising:
applying at least one programming pulse to the at least one PCM cell for programming said respective PCM cell to have a respective definite cell state, the definite cell state being defined by a definite resistance level being the resistance value provided by a definite reading pulse and a type of the at least one applied programming pulse being an annealing pulse or a melting pulse, the respective definite cell state representing two information entities;
applying a first reading pulse to the respective programmed PCM cell to provide a first resistance value;
applying at least a second reading pulse to the respective programmed PCM cell to provide either a second resistance value or a current versus reading-pulse amplitude curve, the first reading pulse and the second reading pulse being different pulses; and
determining the respective definite cell state of the respective programmed PCM cell dependent on the respective provided first resistance value and either the respective provided second resistance value or the respective provided current versus reading-pulse amplitude curve.

2. The method of claim 1, wherein the second reading pulse is a ramp pulse.

3. The method of claim 2, wherein the PCM cell is controlled by two terminals, wherein the respective programming pulse is embodied as a pulse in either one of the terminals and the respective reading pulse is embodied as a pulse in either one of the terminals.

4. The method of claim 3, wherein the two terminals are coupled to a bitline and to a wordline, respectively.

5. The method of claim 4, wherein the programming pulse is embodied as a wordline voltage pulse or a bitline current pulse.

6. The method of claim 5, wherein the reading pulse is embodied as a bitline voltage pulse or bitline current pulse.

7. The method of claim 1, wherein the definite cell state is defined by the definite resistance level and by the phase distribution of the programmed PCM cell, the phase distribution of the programmed PCM cell being dependent on the type of the at least one applied programming pulse being an annealing pulse or a melting pulse.

8. The method of claim 7, wherein the step of determining the respective cell state of the respective programmed PCM cell includes:
determining the resistance level and the phase distribution of the programmed PCM cell dependent on the respective provided first resistance value and either the respective provided second resistance value or the respective provided current versus reading-pulse amplitude curve.

9. The method of claim 8, wherein the step of determining the respective cell state of the respective programmed PCM cell includes determining the type of the applied programming pulse by the steps:
providing a threshold value;
providing the first resistance value and the second resistance value
identifying the applied programming pulse as a melting pulse if the provided measure is greater than the provided threshold value, and
identifying the applied programming pulse as an annealing pulse if the provided measure is less than the provided threshold value.

10. The method of claim 9, wherein the step of determining the respective cell state of the respective programmed PCM cell includes determining the type of the applied programming pulse by the steps:
providing a threshold value in log domain;
measuring the magnitude of the difference between the first resistance value and the second resistance value in log domain;
identifying the applied programming pulse as a melting pulse if the provided measure is greater than the provided threshold value; and
identifying the applied programming pulse as an annealing pulse if the provided measure is less than the provided threshold value.

11. The method claim 9, wherein the step of determining the respective cell state of the respective programmed PCM cell includes determining the type of the applied programming pulse by the steps:
providing a threshold value;
measuring the slope of the provided current vs reading-pulse curve;
identifying the applied programming pulse as a melting pulse if the provided measure is greater than the provided threshold value; and
identifying the applied programming pulse as an annealing pulse if the provided measure is less than the provided threshold value.

12. The method of claim 9, wherein said threshold value is different depending on the definite resistance level.

13. A device for programming at least one multi-level Phase Change Memory, PCM, cell for storing at least two information entities in one resistance level of the PCM cell, comprising:
a first means for applying at least one programming pulse to the at least one PCM cell for programming said respective PCM cell to have a respective definite cell state, the definite cell state being defined by a definite resistance level being the resistance value provided by a definite reading pulse and a type of the at least one applied programming pulse being an annealing pulse or a melting pulse, the respective definite cell state representing two information entities;
a second means for applying a first reading pulse to the respective programmed PCM cell to provide a first resistance value;
a third means for applying at least a second reading pulse to the respective programmed PCM cell to provide either a second resistance value or a current versus reading-pulse amplitude curve, the first reading pulse and the second reading pulse being different pulses; and
a fourth means for determining the respective definite cell state of the respective programmed PCM cell dependent on the respective provided first resistance value and either the respective provided second resistance value or the respective provided current versus reading-pulse amplitude curve.

14. The device of claim 13, wherein the definite cell state is defined by the definite resistance level and by the phase distribution of the programmed PCM cell, the phase distribution of the programmed PCM cell being dependent on the type of the at least one applied programming pulse being an annealing pulse or a melting pulse.

15. Device of claim 14, wherein said fourth means are adapted to determine the resistance level and the phase distribution of the programmed PCM cell dependent on the respective provided first resistance value and either the respective provided second resistance value or the respective provided current versus reading-pulse amplitude curve.

16. The device of one of claim 13, wherein said fourth means comprise first providing means, second providing means and identifying means,
wherein said first providing means are adapted to provide a threshold value, wherein the threshold value is particularly different depending on the definite resistance level, and
wherein said second providing means are adapted to provide a measure being the difference between the first resistance value and the second resistance value,
wherein said identifying means are adapted to identify the applied programming pulse as a melting pulse, if the respective provided measure is greater than the provided threshold value, or as an annealing pulse, if the respective provided measure is less than the provided threshold value.

17. The device of one of claim 13, wherein said fourth means comprise first providing means, second providing means and identifying means, wherein said first providing means are adapted to provide a threshold value in log domain, wherein the threshold value is particularly different depending on the definite resistance level,
wherein said second providing means are adapted to provide a measure being the difference between the first resistance value and the second resistance value, and
wherein said identifying means are adapted to identify the applied programming pulse as a melting pulse, if the respective provided measure is greater than the provided threshold value, or as an annealing pulse, if the respective provided measure is less than the provided threshold value.

18. The device of one of claim 13, wherein said fourth means comprise first providing means, second providing means and identifying means, wherein said first providing means are adapted to provide a threshold value, the threshold value may be different depending on the definite resistance level,
wherein said second providing means are adapted to provide a measure being the slope of the provided current versus reading-pulse amplitude curve,
wherein said identifying means are adapted to identify the applied programming pulse as a melting pulse, if the respective provided measure is greater than the provided threshold value, or as an annealing pulse, if the respective provided measure is less than the provided threshold value.
